(19) United States
(12) Patent Application Publication
(10) Pub. No.: US 2008/0258282 A1
(43) Pub. Date: Oct. 23, 2008

(54) LEAD FRAME FREE PACKAGE AND METHOD OF MAKING

(76) Inventors: Hua Yang, Suzhou (CN); Yong Liu, Scarborough, ME (US)

Correspondence Address: HISCOCK & BARCLAY, LLP, 2000 HSBC PLAZA, 100 Chestnut Street, ROCHESTER, NY, 14604-2404, US

(21) Appl. No.: 11/758,886

(22) Filed: Jun. 6, 2007

Related U.S. Application Data
(60) Provisional application No. 60/913,329, filed on Apr. 23, 2007.

(51) Int. Cl. H01L 23/495; H01L 21/00; H01L 23/02

(52) U.S. Cl. 257/678; 257/675; 438/124; 257/E21.001; 257/E23.031

(57) ABSTRACT

A lead frame free packaged semiconductor device with an exposed heat sink is formed by die bonding the semiconductor device directly to the heat sink and bonding package leads directly to the semiconductor die, and optionally to the heat sink. In an alternative embodiment, a lead frame free packaged semiconductor device with an exposed heat sink is formed by die bonding the semiconductor device directly to the heat sink and wire bonding package leads to the semiconductor die, and optionally to the heat sink.

### CROSS-REFERENCE TO RELATED APPLICATIONS

This application claims the benefit of U.S. Provisional Patent Application Ser. No. 60/913.329, filed Apr. 23, 2007.

### FIELD OF THE INVENTION

This invention relates to packages for semiconductor devices, and more specifically to lead frame free semiconductor packages.

### BACKGROUND OF THE INVENTION

Most semiconductor devices are packaged using a prefabricated lead frame which includes a die bond region and external leads which are connected to various connection points on the die by wire bonding, ball grids, and other attachment methods well known in the industry. While the cost of the lead frame itself is small in comparison to the other costs of producing a packaged semiconductor device for some complex devices, the cost can be of more significance for high quantity semiconductor products which are mature and relatively cheap to manufacture. Since the semiconductor industry is very competitive, a cost savings, even a small one on a piece part basis, can give the provider of the packaged semiconductor device a competitive edge.

Therefore it can be appreciated that a semiconductor package which eliminates the lead frame and results in a lower cost package than almost all of the prior art packages is highly desirable.

### SUMMARY OF THE INVENTION

In an embodiment of the present invention a lead frame free packaged semiconductor die has a heat sink plate with the semiconductor die bonded directly thereto, a plurality of package leads attached directly to the semiconductor die, and encapsulating material encapsulating a portion of the heat sink plate and the semiconductor die and a portion of each of the plurality of package leads.

In another embodiment of the present invention is a lead frame free packaged semiconductor die has a heat sink plate with the semiconductor die bonded directly thereto and a plurality of package leads wire bonded to the semiconductor die and supported solely an encapsulating material which encapsulates a portion of the heat sink plate with the semiconductor die attached and a portion of the package leads.

In still another embodiment of the present invention a method of packaging a semiconductor die includes placing a heat sink plate in a recess in a panelized top jig, bonding a semiconductor die directly to the heat sink, and placing a plurality of package leads in a like plurality of recesses in a panelized bottom jig with a first end of each of the plurality of package leads extends over another recess in the panelized bottom jig. The method further includes applying solder paste to the tips of the first ends of the plurality of package leads, aligning and joining the panelized top jig and the panelized bottom jig such that the tips of the plurality of package leads are in contact with contacts on the semiconductor die, reflow soldering the joined panelized top and bottom jigs to form contacts between the semiconductor die and the plurality of package leads, removing the panelized top jig and placing a top molding plate on the panelized bottom jig, and encapsulating the semiconductor die and portions of the heat sink plate and the plurality of package leads.

In yet another embodiment of the present invention a method of packaging a semiconductor die includes placing a heat sink plate in a first recess in a panelized top jig, bonding a semiconductor die directly to the heat sink, placing a plurality of package leads in a like plurality of additional recesses in the panelized top jig, a first end of each of the plurality of package leads extending over the first recess, wire bonding the first ends to the semiconductor die, placing a molding plate in contact with the panelized top jig, and encapsulating the semiconductor die and the wire bonds and portions of the beat sink plate and the plurality of package leads.

### BRIEF DESCRIPTION OF THE DRAWINGS

The features and advantages of this invention, and the manner of attaining them, will become apparent and be better understood by reference to the following description of the various embodiments of the invention in conjunction with the accompanying drawings, wherein:

FIG. 1 is a flow chart of the processes for making several embodiments of the present invention;

FIG. 2 is a flow chart of the processes for making several additional embodiments of the present invention;

FIGS. 3A and 3B are plan views of portions of panelized top jig according to two different embodiments of the invention with heat sink plates placed in recesses therein;

FIGS. 4A and 4B are plan views of the portions of the panelized top jig shown in FIGS. 3A and 3B, respectively, with solder paste applied to the heat sink plates;

FIGS. 5A and 5B are plan views of the portions of the panelized top jig shown in FIGS. 4A and 4B, respectively, with semiconductor devices soldered to the heat sink plates, and with center leads also soldered to some of the heat sink plates;

FIGS. 6A and 6B are plan views of portions of panelized bottom jig according to two other different embodiments of the invention with recesses formed in the panel;

FIGS. 7A and 7B are plan views of the portions of the panelized bottom jig shown in FIGS. 6A and 6B, respectively, with various package leads placed in some of the recesses;

FIGS. 8A and 8B are plan views of the portions of the panelized bottom jig shown in FIGS. 7A and 7B, respectively, with solder paste applied to end portions of the package leads;

FIGS. 9A and 9B are end views of one each of the subassemblies of the portions of the panelized bottom jig shown in FIGS. 8A and 8B, respectively;

FIGS. 10A and 10B are end views of one each of the subassemblies of the portions of the panelized top jig shown in FIGS. 5A and 5B flipped over and soldered to one each of the subassemblies of the portions of the panelized bottom jig shown in FIGS. 9A and 9B, respectively to form two assemblies;

FIG. 11 is a side view of the assembly shown in FIG. 10A;

FIG. 12 is a side view of the assembly shown in FIG. 10B;

FIG. 13 is a plan view of the assembly of FIG. 11 after an encapsulation process;

FIG. 14 is a plan view of the assembly of FIG. 12 after an encapsulation process;

FIG. 15 is a cross section taken along line 15-15 in FIG. 13;

FIG. 16 is a cross section taken along line 16-16 in FIG. 13;

FIG. 17 is a plan view of plan view of an assembly according to another embodiment of the present invention prior to an encapsulation operation;

FIG. 18 is a plan view of plan view of an assembly according to yet another embodiment of the present invention prior to an encapsulation operation;

FIG. 19 is a cross section taken along line 19-19 in FIG. 17;

FIG. 20 is a cross section taken along line 20-20 in FIG. 18;

FIG. 21 is the cross section of FIG. 19 after a top molding plate has been put in place and the assembly encapsulated;

FIG. 22 is the cross section of FIG. 20 after a top molding plate has been put in place and the assembly encapsulated; and

FIG. 23 is a cross section of an alternative embodiment to the embodiment shown in FIG. 19.

It will be appreciated that for purposes of clarity, and where deemed appropriate, reference numerals have been repeated in the figures to indicate corresponding features. Also, the relative size of various objects in the drawings has in some cases been distorted to more clearly show the invention. The examples set out herein illustrate several embodiments of the invention but should not be construed as limiting the scope of the invention in any manner.

### DETAILED DESCRIPTION

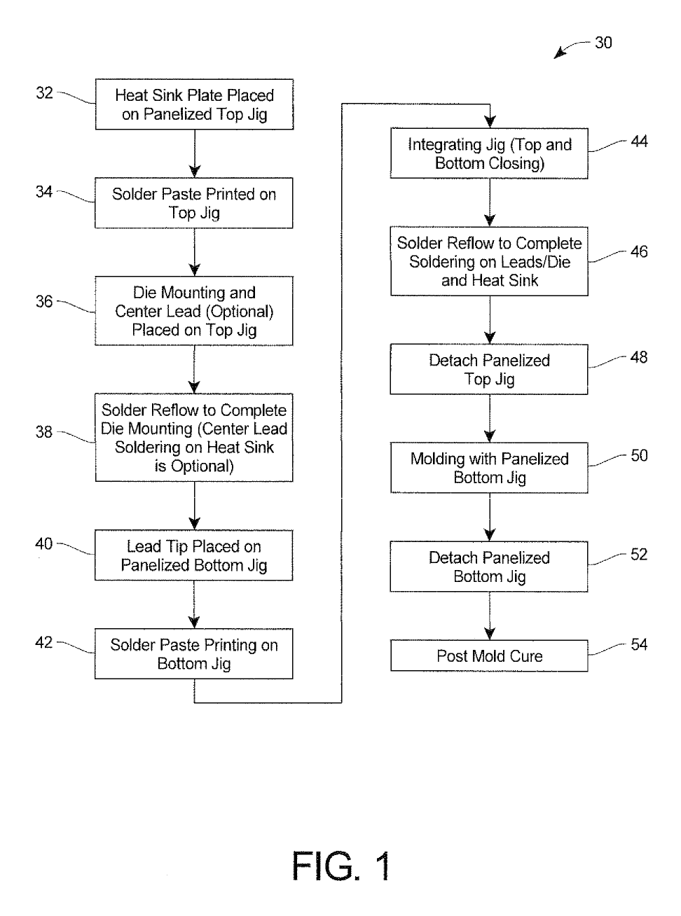

Turning now to the drawings, FIG. 1 is a flow chart 30 of the processes for making several embodiments of the present invention in which semiconductors are packaged without lead frames or wire bonds. As shown in FIG. 1 heat sink plates are placed in a panelized top jig as indicated in box 32. Then solder paste is applied to the heat sink plates as indicated in box 34, following by placing a semiconductor die on the solder paste and optionally also placing a center lead on the solder paste as indicted by box 36. Next, as indicated in box 38, the solder paste is reflowed to complete the die bonding and to solder the center lead, if present, to the heat sink plate.

Lead tips are placed in a panelized bottom jig as indicated in box 40, and solder paste is printed on the ends of the lead tips as indicated in box 42. The top and bottom jigs are integrated as indicated in box 44, and then the assembly is reflow soldered to solder the lead tips to the die and optionally to the center leads as indicated in box 46.

The panelized top jig is then detached as indicated in box 48 and the bottom jig is used in a molding operation as indicated in box 50. After the assembly is molded, the bottom jig is detached as indicated in box 52, and the assembly undergoes a post mold cure as indicated in box 54.

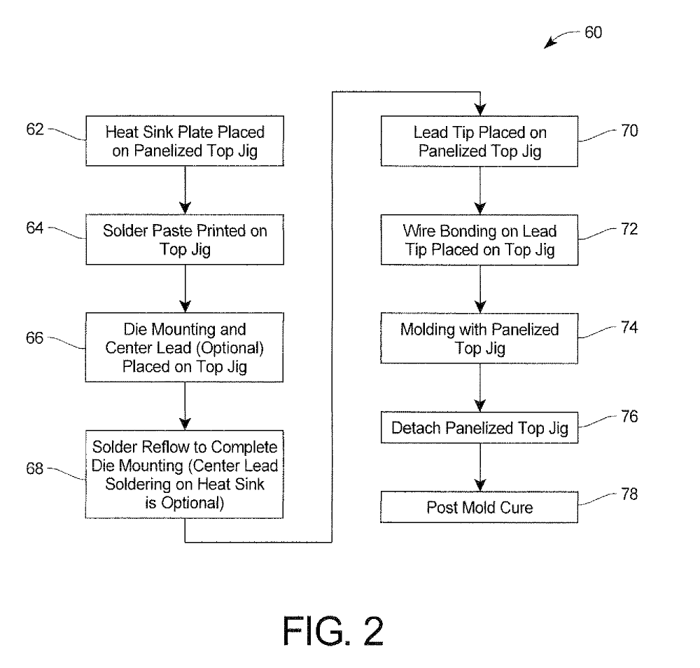

FIG. 2 is a second flow chart 60 of the processes for making several additional embodiments of the present invention in which semiconductors are packaged using wire bonds and without lead frames. As shown in FIG. 2 heat sink plates are placed in a panelized top jig as indicated in box 62. Then solder paste is applied to the heat sink plates as indicated in box 64, following by placing a semiconductor die on the solder paste and optionally also placing a center lead on the solder paste as indicted by box 66. Next, as indicated in box 68, the solder paste is reflowed to complete the die bonding and to solder the center lead, if present, to the heat sink plate.

Lead tips are then placed in the panelized top jig as indicated in box 70, and lead tips are wire bonded to the die and optionally to the center lead as indicated in box 72. The top jig is used in a molding operation as indicated in box 74. After the assembly is molded, the top jig is detached as indicated in box 76, and the assembly undergoes a post mold cure as indicated in box 78.

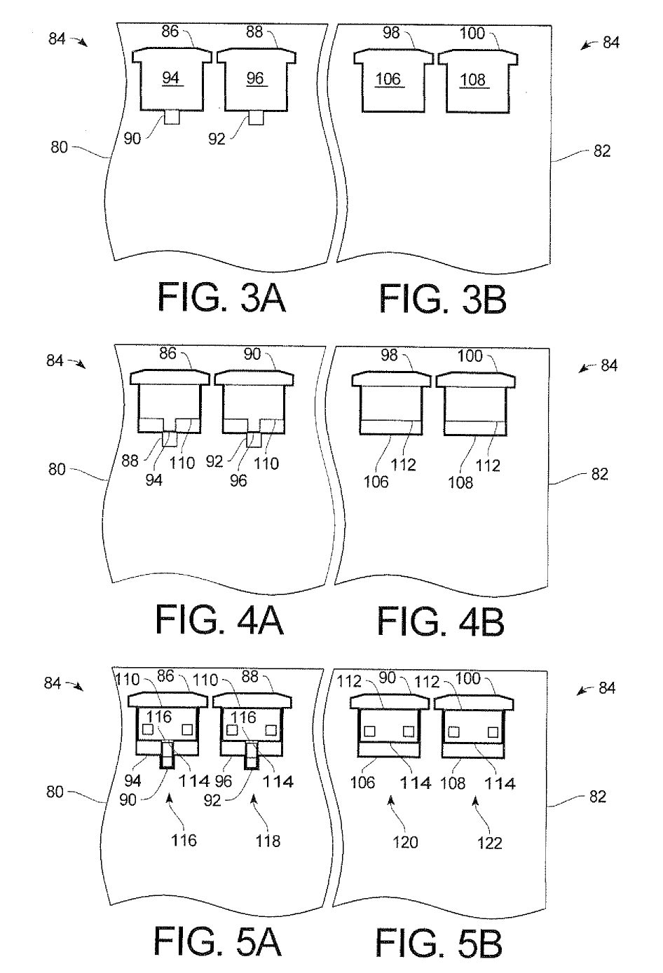

FIGS. 3A and 3B are plan views of portions 80 and 82, respectively, of a panelized top jig 84 according to two different embodiments of the present invention with recesses 86, 88, 90 and 92 formed in the portion 80 with heat sink plates 94 and 96 in the recesses 88 and 90, respectively, which corresponds to the process shown the process step in box 32 of FIG. 1. Portion 82 has recesses 98 and 100 formed in the portion 82 with heat sink plates 106 and 108 laid in the recesses 98 and 100, respectively, which also corresponds to the process shown in box 32 of FIG. 1.

FIGS. 4A and 4B are plan views of the portions 80, 82 shown in FIGS. 3A and 3B respectively, with solder paste 110 applied to the heat sink plates 94, 96, and solder past 112 applied to the heat sink plates 106, 108 in FIG. 3B which corresponds to the process shown in box 34 of FIG. 1.

FIGS. 5A and 5B are plan views of the portions 80, 82 of the panelized top jig shown in FIGS. 4A and 4B, respectively, with semiconductor devices 114 mounted and soldered to the heat sink plates 94, 96, 106, 108 after the solder reflow process indicated in box 38 of FIG. 1 to form four subassemblies 116, 118, 120, and 122, respectively, which corresponds to the processes shown in boxes 36 and 38 of FIG. 1. Center leads 116 have also been soldered to the heat sink plates 88, 90 during the solder reflow process which corresponds to the process shown in box 36.

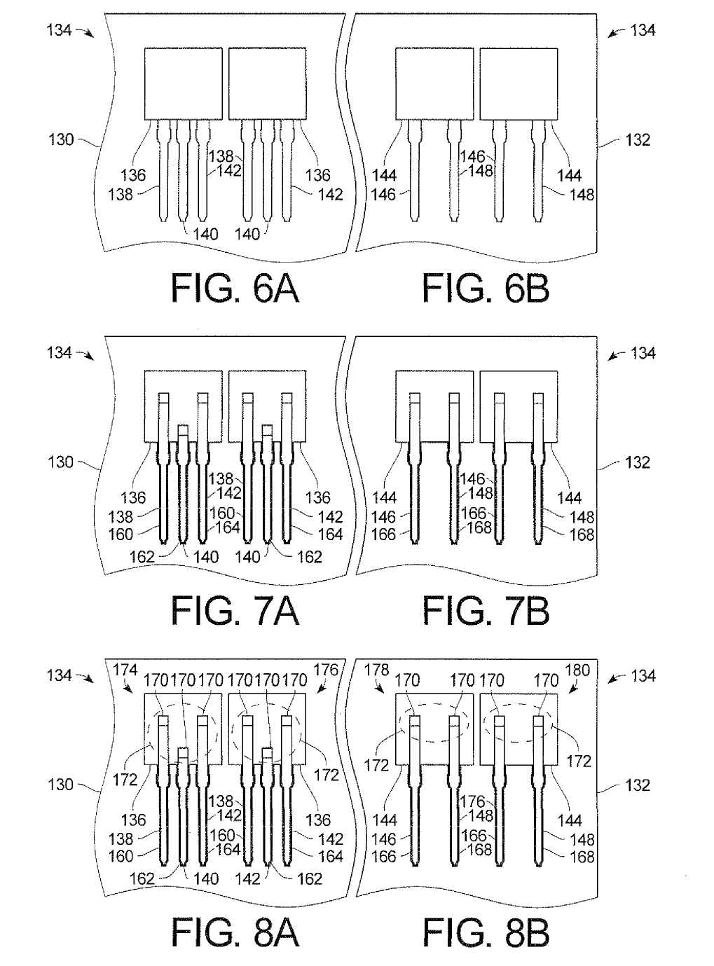

FIGS. 6A and 3B are plan views of portions 130 and 132 of a panelized bottom jig 134 with recesses 136, 138, 140, and 142 formed in the portion 130, and recesses 144, 146, and 148 formed in the portion 132.

FIGS. 7A and 7B are plan views of the portions 130, 132 shown in FIGS. 6A and 6B, respectively, with package leads 160, 162, and 164 placed in the recesses 138, 140, and 142, respectively, and package leads 166, and 168 placed in the recesses 146 and 148, respectively, which corresponds to the process shown in box 40 of FIG. 1

FIGS. 8A and 8B are plan views of the portions 130, 132 shown in FIGS. 7A and 7B, respectively, with solder paste 170 applied to end portions 172 of the package leads 160-168, which corresponds to the process shown in box 42 of FIG. 1, to form four subassemblies 174, 176, 178, and 180.

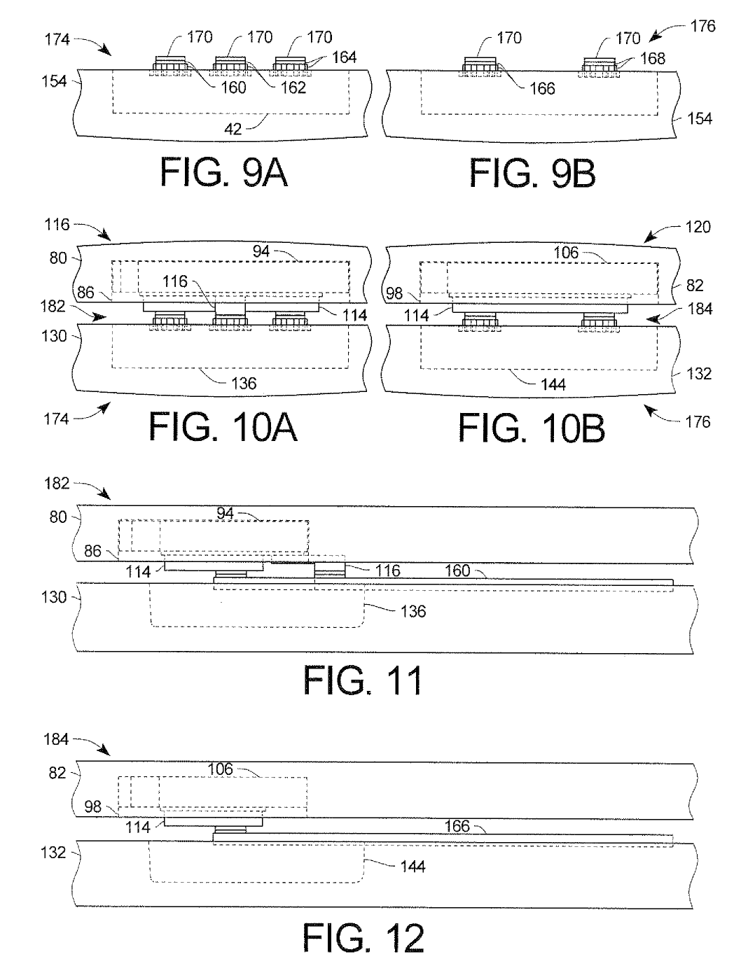

FIGS. 9A and 93 are end views of the subassemblies 174 and 178 shown in FIGS. 8A and 8B, respectively.

FIGS. 10A and 10B are end views of the subassemblies 116 and 120 shown in FIGS. 5A and 5B flipped over and reflow soldered to the subassemblies 174 and 178 shown in FIGS. 9A and 9B, respectively, which corresponds to the process shown in box 46 of FIG. 1 to form two assemblies 182 and 184 which corresponds to the processes shown in boxes 44 and 46 of FIG. 1.

FIG. 11 is a side view of the assembly 182, and FIG. 12 is a side view of the assembly 184. The heat sink plates 94 and 106 are connected to the substrate of the semiconductor dies 114 and may be used as an electrical connection to the assemblies 182 and 184, respectively.

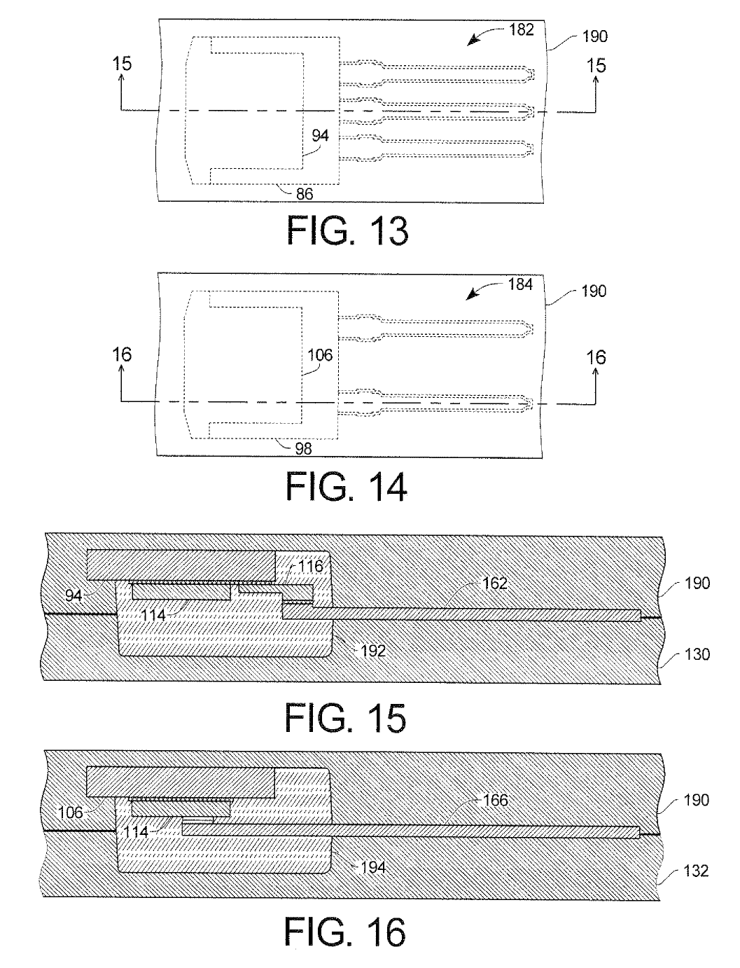

FIG. 13 is a plan view of the assembly 182 after removal of the panelized top jig 84, which corresponds to the process shown in box 48 of FIG. 1, the placement of a top molding plate 190 over the panelized bottom jig 134, and an encapsulation process, which corresponds to the process shown in box 50 of FIG. 1, has been performed.

FIG. 15 is a plan view of the assembly 184 after removal of the panelized top jig 84, which corresponds to the process shown in box 48 of FIG. 1, the placement of the top molding plate 190 over the panelized bottom jig 134, and an encapsulation process, which corresponds to the process shown in box 50 of FIG. 1, has been performed.

FIG. 15 is a cross section taken along line 15-15 in FIG. 13 showing the molded encapsulating material 192, and FIG. 16 is a cross section taken along line 16-16 in FIG. 13 showing the molded encapsulating material 194.

The two assemblies 182, 184 are detached from the top molding plate 190 and the panelized bottom jig 134 which corresponds to the process shown in box 52 of FIG. 1, and the assemblies 182, 184 then undergo post mold cure which corresponds to the process shown in box 54 of FIG. 1. After these processes. The assembly 182 is a packaged semiconductor device in an I PAK type package, or a D PAK type package if the center package lead 224 is shortened, and the assembly 184 is a packaged semiconductor device in a D Pak package.

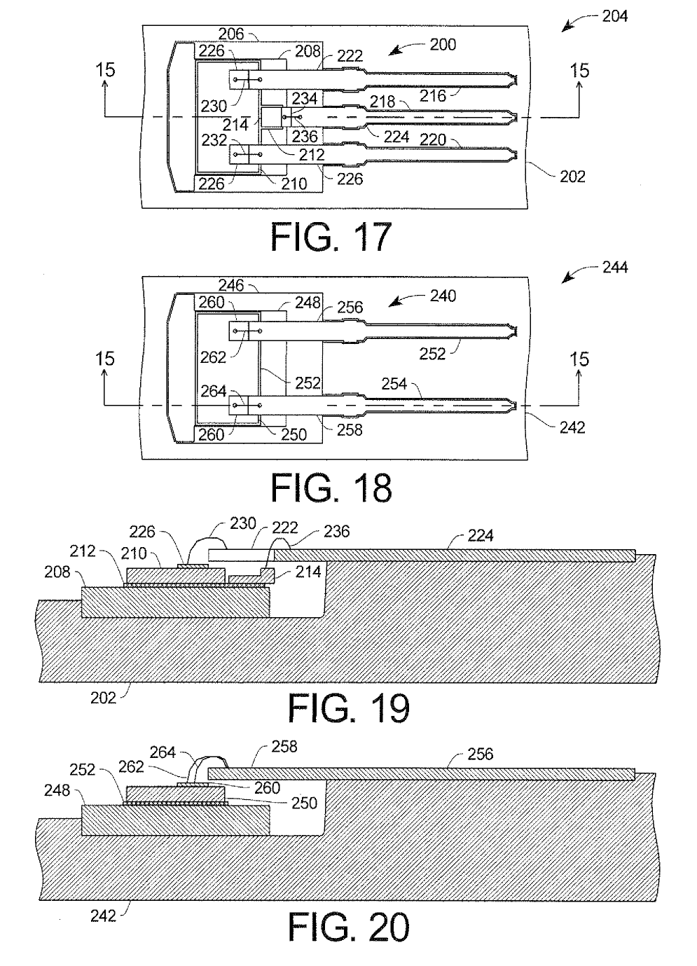

FIG. 17 is a plan view of an assembly 200 prior to encapsulation according to the first of two additional embodiments of the present invention. Shown in FIG. 17 is a portion 202 of another panelized bottom jig 204. Portion 202 has a recess 206 with a heat sink plate 208 placed therein and a semiconductor die 210 die bonded to the heat sink plate 208 after solder paste 212 has been printed on the heat sink plate 208, and the die 210 reflow soldered onto the heat sink plate 208 which corresponds to the processes shown in boxes 62, 64, 66, and 68 of FIG. 2. An optional center lead 214 is also soldered to the heat sink plate 208 in the same manner as the semiconductor die 210. Three additional recesses 216, 218, and 220 are in the portion 202 and hold package leads 222, 224, and 226, respectively which corresponds to the process shown in box 70 of FIG. 2. The package leads 222 and 226 extend approximately to the edges of wire bonding pads 228 of the semiconductor die 210 and are wire bonded to the semiconductor die 210 by wire bonds 230 and 232, respectively, which corresponds to the process shown in box 72 of FIG. 2. The package lead 224 extends to approximately the edge 234 of the center lead 212 farthest from the semiconductor die 210, and is connected to the center lead 214 by a wire bond 236. Thus the package lead 224 is in electrical contact with the substrate of the semiconductor die 210. The heat sink plate 208 is connected to the substrate of the semiconductor die 210 and may be used as a third terminal of the assembly 200.

FIG. 18 is a plan view of an assembly 240 prior to encapsulation according to the second of the two additional embodiments of the present invention. Shown in FIG. 18 is a portion 242 of another panelized bottom jig 244. Portion 242 has a recess 246 with a heat sink plate 248 placed therein and a semiconductor die 250 die bonded to the heat sink plate 248 after solder paste 252 has been printed on the heat sink plate 248, and the semiconductor die 250 reflow soldered onto the heat sink plate 248 which corresponds to the processes shown in boxes 62, 64, 66, and 68 of FIG. 2. Two additional recesses 252 and 254 are in the portion 242 and hold package leads 256 and 258, respectively which corresponds to the process shown in box 70 of FIG. 2. The package leads 256 and 258 extend approximately to the edges of the wire bonding pads 260 of the semiconductor die 250 and are wire bonded to the semiconductor die 250 by wire bonds 262 and 264, respectively, which corresponds to the process shown in box 72 of FIG. 2. The heat sink plate 248 is connected to the substrate of the semiconductor die 240 and may be used as an electrical connection to the assembly 240.

FIG. 19 is a cross section taken along line 19-19 in FIG. 17, and FIG. 20 is a cross section taken along line 20-20 in FIG. 18.

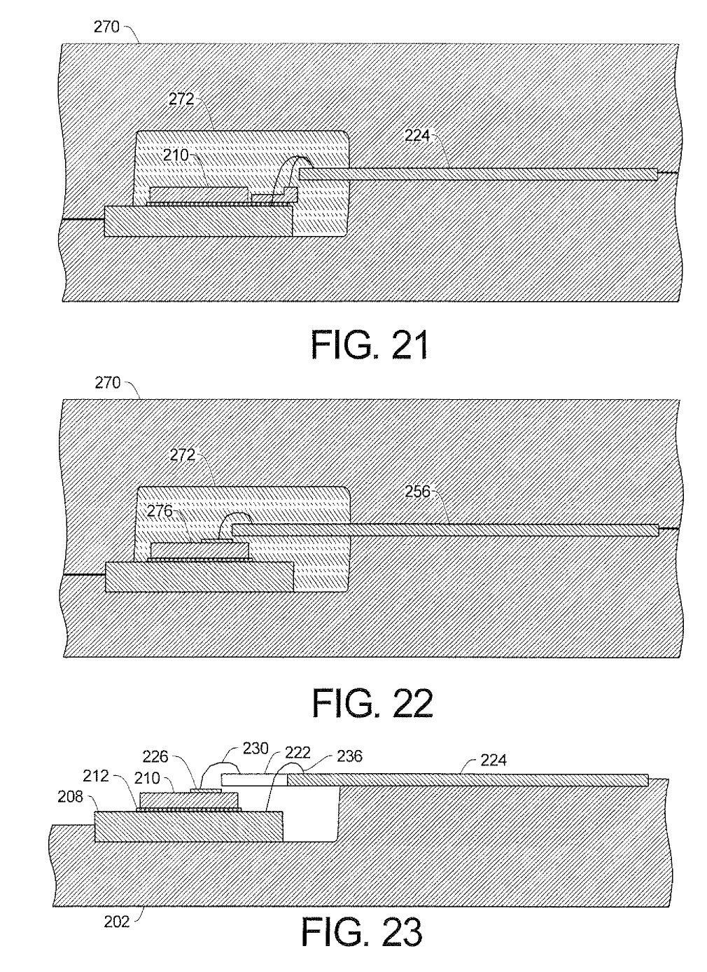

FIG. 21 is the cross section of FIG. 19 after a top molding plate 270 has been put in place and the assembly encapsulated with encapsulating material 272, which corresponds to the process shown in box 74 of FIG. 2. FIG. 22 is the cross section of FIG. 20 after the top molding plate 270 has been put in place and the assembly encapsulated with encapsulating material 272 which corresponds to the process shown in box 74 of FIG. 2.

The two assemblies 200, 240 are detached from the top molding plate 270 and the panelized bottom jigs 204 and 244, respectively, which corresponds to the process shown in box 76 of FIG. 2, and the assemblies 200, 240 then undergo post mold cure which corresponds to the process shown in box 78 of FIG. 2. After these processes, The assembly 200 is a packaged semiconductor device in an I PAK type package, or a D PAK type package if the center package lead 224 is shortened, and the assembly 240 is a packaged semiconductor device in a D Pak package.

FIG. 23 is a cross section of an assembly 280 which is an alternative embodiment to the embodiment shown in FIG. 19. In FIG. 22 the center lead 214 is not used, and the package lead 224 is wire bonded directly to the heat sink plate 208.

While the invention has been described with reference to preferred embodiments, it will be understood by those skilled in the art that various changes may be made and equivalents may be substituted for elements thereof to adapt to particular situations without departing from the scope of the invention. For example, other types of semiconductor packages with integral exposed heat sinks, such as the TO-220 package, can be assembled using the present invention. Therefore, it is intended that the invention not be limited to the particular embodiments disclosed as the best mode contemplated for carrying out this invention, but that the invention will include all embodiments falling within the scope and spirit of the appended claims.

1. A lead frame free packaged semiconductor die comprising:
a) a heat sink plate with the semiconductor die bonded directly thereto;
b) a plurality of package leads attached directly to said semiconductor die; and
c) encapsulating material encapsulating a portion of said heat sink plate and said semiconductor die and a portion of each of said plurality of package leads.

2. The package of claim 1 wherein said semiconductor die has an electrical terminal that makes electrical contact with said heat sink plate directly through a die bonding material that bonds said semiconductor die to said heat sink plate.

3. The package of claim 2 further comprising a center lead attached to, and between, said heat sink plate and another package lead.

4. The package of claim 1 wherein the number of said package leads is three.

5. The package of claim 2 wherein the number of said package leads is two.

6. The package of claim 1 wherein said semiconductor die is bonded to said heat sink plate with solder.

7. The package of claim 1 wherein said plurality of package leads are attached directly to said semiconductor die with solder.

8. The package of claim 1 wherein each of said plurality of package leads is “L” shaped.

9. The package of claim 3 wherein said center lead extends past an edge of said heat sink plate.

10. The package of claim 3 wherein said center lead is “L” shaped.

11. The package of claim 10 wherein said attachment of said center lead to said another package lead is at a location proximate to, by not over, said heat sink plate.

12. A lead frame tree packaged semiconductor die comprising:
a) a heat sink plate with the semiconductor die bonded directly thereto;
b) a plurality of package leads wire bonded to said semiconductor die; and
c) encapsulating material encapsulating a portion of said heat sink plate and said semiconductor die and a portion of each of said plurality of package leads.

13. The package of claim 12 wherein said semiconductor die has an electrical terminal that makes electrical contact with said heat sink plate directly through a die bonding material that bonds said semiconductor die to said heat sink plate.

14. The package of claim 13 further comprising a center lead attached to, and between, said heat sink plate and another package lead.

15. The package of claim 12 wherein the number of said package leads is three.

16. The package of claim 13 wherein the number of said package leads is two.

17. The package of claim 12 wherein said semiconductor die is bonded to said heat sink plate with solder.

18. The package of claim 12 wherein another package lead is wire bonded to said heat sink plate.

19. The package of claim 12 wherein each of said plurality of package leads is “L” shaped.

20. The package of claim 14 wherein said center lead extends past an edge of said heat sink plate.

21. The package of claim 14 wherein said center lead is “L” shaped.

22. A method of packaging a semiconductor die comprising the steps of:
a) placing a heat sink plate in a recess in a panelized top jig;
b) bonding a semiconductor die directly to said heat sink;
c) placing a plurality of package leads in a like plurality of recesses in a panelized bottom jig with a first end of each of said plurality of package leads extends over another recess in said panelized bottom jig;
d) applying solder paste to the tips of said first ends of said plurality of package leads;
e) aligning and joining said panelized top jig and said panelized bottom jig such that said tips of said plurality of package leads are in contact with contacts on said semiconductor die;
f) reflow soldering said joined panelized top and bottom jigs to form contacts between said semiconductor die and said plurality of package leads;
g) removing said panelized top jig and placing a top molding plate on said panelized bottom jig; and
h) encapsulating said semiconductor die and portions of said heat sink plate and said plurality of package leads.

23. The method of claim 22 wherein said step of bonding said semiconductor die to said heat sink plate comprises putting solder paste on said heat sink plate, placing said semiconductor die on said solder plate, and reflowing said solder paste.

24. The method of claim 22 further including bonding a center lead to said heat sink plate and another package lead.

25. The method of claim 23 further including bonding a center lead to said heat sink plate and another package lead wherein said center lead is bonded to said heat sink plate in the same manner as said semiconductor die is bonded to said heat sink plate, and said center lead is bonded to said another package lead in the same manner as said plurality of package leads are bonded to said semiconductor die

26. A method of packaging a semiconductor die comprising the steps of:
a) placing a heat sink plate in a first recess in a panelized top jig;
b) bonding a semiconductor die directly to said heat sink;
c) placing a plurality of package leads in a like plurality of additional recesses in said panelized top jig, a first end of each of said plurality of package leads extending over said first recess;
d) wire bonding said first ends to said semiconductor die;
e) placing a molding plate in contact with said panelized top jig; and
f) encapsulating said semiconductor die and said wire bonds and portions of said heat sink plate and said plurality of package leads.

27. The method of claim 26 wherein said step of bonding said semiconductor die to said heat sink plate comprises putting solder paste on said heat sink plate, placing said semiconductor die on said solder plate, and reflowing said solder paste.

28. The method of claim 26 further including bonding a center lead to said heat sink plate and another package lead.

29. The method of claim 26 further including bonding a center lead to said heat sink plate and another package lead wherein said center lead is bonded to said heat sink plate in the same manner as said semiconductor die is bonded to said heat sink plate, and said center lead is bonded to said another package lead in the same manner as said plurality of package leads are bonded to said semiconductor die.

30. The method of claim 26 further including wire bonding another package lead to said heat sink plate.
